(19) United States
(12) Patent Application Publication
(10) Pub. No.: US 2026/0324477 A1
(43) Pub. Date: Oct. 15, 2026

(54) LOOP-BACK REDISTRIBUTION LAYER DESIGN TO IMPROVE INTEGRATED CIRCUIT PACKAGE RELIABILITY

(71) Applicant: XILINX, INC., San Jose, CA (US)

(72) Inventors: Myongseob KIM, Pleasanton, CA (US); Henley LIU, San Jose, CA (US); Cheang Whang CHANG, Mountain View, CA (US)

(21) Appl. No.: 19/177,990

(22) Filed: Apr. 14, 2025

(51) Int. Cl. H01L 23/498; H01L 21/48; H01L 23/00

(52) U.S. Cl. CPC H10W 70/685; H10W 70/05; H10W 70/095; H10W 70/099; H10W 70/65; H10W 90/701; H10W 90/724

(57) ABSTRACT

“Loop-back” full fan-out backside redistribution layer (RDL) is disclosed which provides higher reliability and fewer failures compared to full stacked RDL designs, without sacrificing solder bump spacing and area density. Loop-back trace layouts also enable higher solder bump density. Undesirable parasitic capacitances in high-speed gigabit transfer and/or input-output circuits caused by overlapping of straight traces at different RDL layers may be reduced by rotating the straight traces by an acute angle to minimize trace overlap and/or increase the distance between traces at different levels in the RDL layers.

### TECHNICAL FIELD

Embodiments of the present disclosure generally relate to integrated circuit design, and in particular, to using a loop-back redistribution layer (RDL) design to improve integrated circuit package reliability.

### BACKGROUND

A redistribution layer (RDL) is a layer of insulating material having patterned metal thereon and used for electrical interconnects to redistribute the input-output access to different parts (circuits) of an integrated circuit (IC) die and make it easier to connect to microbumps on the IC die at desired locations thereof. Multi-layer RDL with organic dielectric materials between the wiring metal layer(s) is commonly used in fan-out and 2.5D/3D integrated circuit (IC) packaging. In multi-layer RDL, stacked backside RDL, e.g., a chimney of stacked metal and vias can be used to connect to dense solder bumps or microbumps, but its reliability is more susceptible to failures including cracks and delamination. The other types of RDL via construction, such as full fan-out backside RDL and RDL-partial fan-out backside RDL have better reliability, but it's very difficult to incorporate these types of RDL via constructions in dense solder bump layouts due to tight spacing of the solder bumps and/or design rule constraints.

Referring to FIGS. 1A-1C, depicted are prior art schematic elevation diagrams of multilayer RDL constructions of stacked backside RDL 120 (FIG. 1A), partial fan-out backside RDL 122 (FIG. 1B), and full fan-out backside RDL 124 (FIG. 1C). The stacked backside RDL 120 comprises a solder bump 102, backside via for solder bump 104, backside second metal layer 106, backside second via 108, backside first metal layer 110a, backside first via 112a, through-silicon via (TSV) 116a and an interposer substrate 114a. The backside via for solder bump 104, backside second metal layer 106, backside second via 108, backside first metal layer 110a, backside first via 112a, are conductive materials, such as for example but not limited to aluminum and copper, and are sandwiched between layers of insulating materials, e.g., backside RDL (re-distribution layers) 118 to form a multilayer RDL that is used to connect the circuits in the interposer substrate 114a to the solder bumps 102. Each circuit node of the interposer substrate 114a is electrically coupled thorough the TSV 116a, backside first via 112a, backside first metal layer 110a, backside second via 108, backside second metal layer 106, and backside via for solder bump 104 to the solder bump 102. The backside RDL 118 is attached to a face of the interposer substrate 114a.

The stacked backside RDL 120 construction is adapted to connect to dense (closely spaced) solder bumps 102 but is more susceptible to reliability failures including cracks and delamination. The partial fan-out backside RDL 122 and the full fan-out backside RDL 124 constructions have better reliability, but are very difficult to incorporate them in dense solder bump layouts due to tight space or design rule constraint. The elongated backside first metal layer 110b and 110c, and backside second metal layer 106c require more layout area and thus inhibits use for dense solder bump layouts.

Referring to FIG. 2, depicted is a schematic layout diagram of keep out zones on a face of an IC die. Process tuning can help improve reliability for stacked backside RDL 120, but the improvement may be limited for a die/interposer of large area. It is possible to apply a keep-out-zone (KoZ), shown in FIG. 2, for signal solder bumps at die corners to reduce the risk of reliability failures of the stacked backside RDL 120, but at the cost of an increase in die size.

Another way to reduce reliability failures is to use partial fan-out backside RDL 122 or full fan-out backside RDL 124 instead of stacked backside RDL 120, but their use requires larger die area, prohibiting the usage for input-output and gigabit transfer circuits that require high density solder bumps for interconnections thereto. Referring to FIGS. 3A and 3B, depicted are prior art schematic (FIG. 3A) plan and (FIG. 3B) elevation diagrams of RDL Line via type 1 construction. In basic full fan-out backside RDL 124 (type 1) construction, a solder bump 102 is placed far away from a TSV 116 or a vias (not shown) connected to the rest of the IC die 114 through RDL layers 118. This is a very typical design to fan out the traces from a die to a package substrate (not shown). However, the layout shown in the plan view of FIG. 3A is not compatible with high density solder bump layout.

### SUMMARY

In one example of the disclosure, a method for forming high density connections in a multi-level redistribution layer (RDL) attached to a face of an integrated circuit (IC) substrate includes forming a plurality of through-silicon vias (TSVs) in the IC substrate. The IC substrate may be an interposer, package substrate, or a printed circuit board (PCB). Electrically connecting a backside first via to each of the plurality of TSVs at the face of the IC interposer substrate. Electrically connecting a backside first metal layer trace to each backside first via, on an opposite side of the backside first via connection to the TSV. Electrically connecting a backside second via to each of the backside first metal layer traces, on an opposite side of the backside first metal layer trace connection to the backside first via. Electrically connecting a backside second metal layer trace to each backside second via, on an opposite side of the backside second via connection to the backside first metal layer trace. Electrically connecting a backside via for solder bump to each of the backside second metal layer traces, on an opposite side of the backside second metal layer trace connection to the backside second via. Electrically connecting a solder bump to each of the backside via for solder bumps, on an opposite side of the backside via for solder bump connected to the backside second metal layer trace. Wherein the backside first metal layer trace loops between the backside first via and backside second via, and the backside second metal layer trace loops between the backside second via and backside via for solder bump.

In one example of the disclosure, an integrated circuit includes an integrated circuit (IC) interposer substrate. A plurality of through-silicon vias (TSVs) in the IC interposer substrate. A multi-level redistribution layer (RDL or alternatively build-up layers) attached to a face of the IC interposer substrate. A plurality of backside first vias in the multi-level RDL, each backside first via electrically connected at the face of the IC die to a respective one of the plurality of TSVs. A plurality of backside first metal layer traces in the multi-level RDL, each backside first metal layer trace electrically connected to a respective one of the plurality of backside first vias. A plurality of backside second vias in the multi-level RDL, each backside second via electrically connected to a respective one of the plurality of backside first metal layer traces. A plurality of backside second metal layer traces in the multi-level RDL, each backside second metal layer trace electrically connected to a respective one of the plurality of backside second vias. A plurality of backside via for solder bumps in the multi-level RDL, each backside via for solder bump electrically connected to a respective one of the plurality of backside second metal layer traces. A plurality of solder bumps on the multi-level RDL, each solder bump electrically connected to a respective one of the plurality of backside via for solder bumps. The backside first metal layer traces loop between respective ones of the backside first vias and backside second vias. The backside second metal layer traces loop between respective ones of the backside second vias and backside via for solder bumps.

In one example of the disclosure, an integrated circuit includes an integrated circuit (IC) interposer substrate. A plurality of through-silicon vias (TSVs) in the IC interposer substrate. A multi-level redistribution layer (RDL) attached to a face of the IC interposer substrate. A plurality of backside first vias in the multi-level RDL, each backside first via electrically connected at the face of the IC interposer substrate to a respective one of the plurality of TSVs. A plurality of backside first metal layer traces in the multi-level RDL, each backside first metal layer trace electrically connected to a respective one of the plurality of backside first vias. A plurality of backside second vias in the multi-level RDL, each backside second via electrically connected to a respective one of the plurality of backside first metal layer traces. A plurality of backside second metal layer traces in the multi-level RDL, each backside second metal layer trace electrically connected to a respective one of the plurality of backside second vias. A plurality of backside via for solder bumps in the multi-level RDL, each backside via for solder bump electrically connected to a respective one of the plurality of backside second metal layer traces. A plurality of solder bumps on the multi-level RDL, each solder bump electrically connected to a respective one of the plurality of backside via for solder bumps. The backside first metal layer and backside second metal layer traces associated with adjacent TSVs are rotated so that they do not overlap.

### BRIEF DESCRIPTION OF THE DRAWINGS

So that the manner in which the above recited features of the present invention can be understood in detail, a more particular description of the invention, briefly summarized above, may be had by reference to examples, some of which are illustrated in the appended drawings. It is to be noted, however, that the appended drawings illustrate only typical examples of this invention and are therefore not to be considered limiting of its scope, for the invention may admit to other equally effective examples.

FIGS. 1A-1C illustrate prior art schematic elevation diagrams of multilayer RDL constructions of stacked backside RDL, partial fan-out backside RDL and full fan-out backside RDL.

FIG. 2 illustrates a schematic layout diagram of keep out zones on a face of an IC die.

FIGS. 3A and 3B illustrate prior art schematic plan and elevation diagrams of full fan-out backside RDL construction.

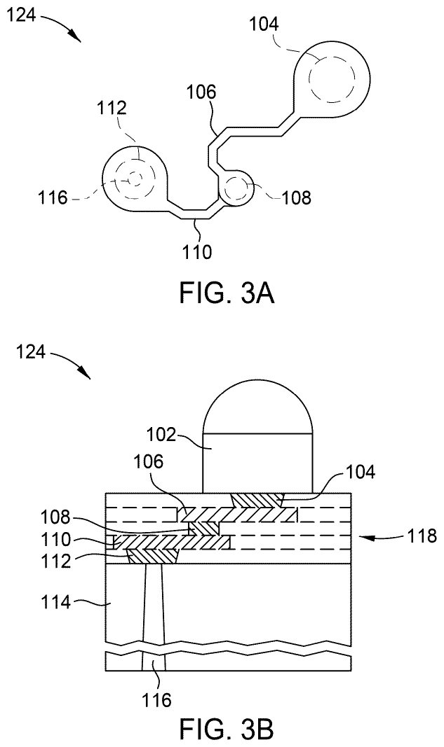

FIGS. 4A-4C illustrate representative schematic plan and elevation diagrams of loop-back fan-out backside RDL construction, according to an example.

FIG. 5 illustrates a prior art schematic plan diagram of full fan-out backside RDL construction having overlap of traces.

FIG. 6 illustrates a representative schematic plan diagram of full fan-out backside RDL construction having traces rotated by an acute angle, according to an example.

FIG. 7 is a flow diagram of one example of a method for forming high density connections in a multi-level redistribution layer (RDL) attached to a core of an integrated circuit (IC) substrate.

FIG. 8 depicts a schematic side view of a chip package having a loop-back fan-out backside RDL.

To facilitate understanding, identical reference numerals have been used, where possible, to designate identical elements that are common to the figures, and a lower-case letter added where the elements are substantially the same. It is contemplated that elements of one embodiment may be beneficially incorporated in other embodiments.

### DETAILED DESCRIPTION

Various features are described hereinafter with reference to the drawing figures. It should be noted that the drawing figures may or may not be drawn to scale and that the elements of similar structures or functions are represented by like reference numerals throughout the drawing figures. It should be noted that the drawing figures are only intended to facilitate the description of the features of the examples. They are not intended as an exhaustive description of the examples below or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described. Referring now to the drawing figures, the details of examples are representative layouts schematically illustrated. Like elements in the drawing figures will be represented by like numbers, and similar elements will be represented by like numbers with a different lower-case letter suffix.

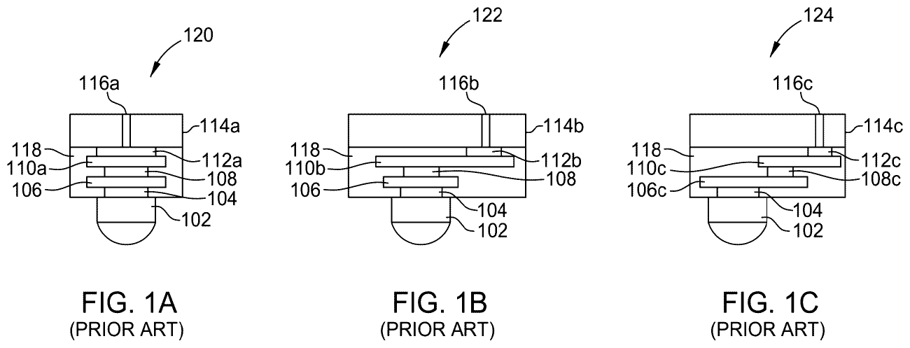

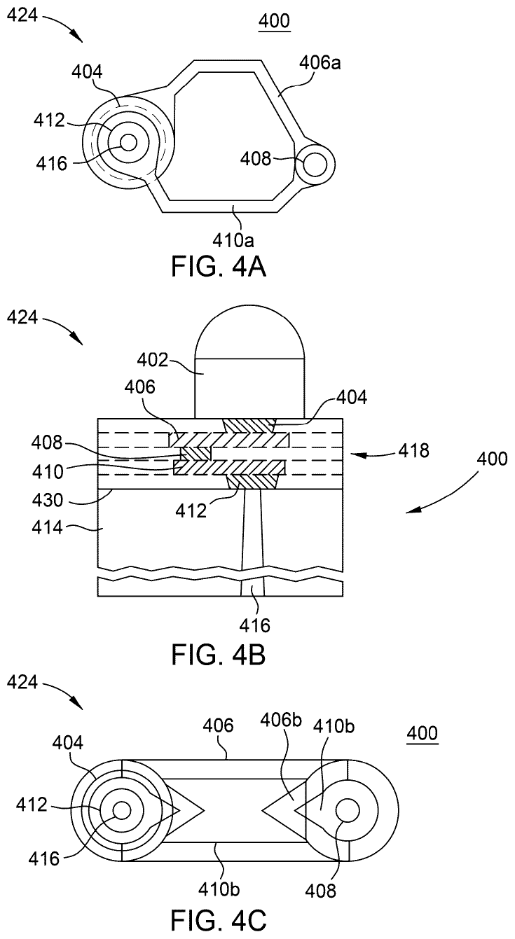

Referring to FIGS. 4A-4C, depicted are representative schematic plan (FIGS. 4A and 4C) and elevation (FIG. 4B) diagrams of loop-back fan-out backside RDL construction, according to an example, that is part of an integrated circuit (IC) substrate 400. The IC substrate 400 may be an interposer, package substrate, or a printed circuit board (PCB). The IC substrate 400 includes a loop-back fan-out backside RDL 424 formed on a face 430 of a core 414. Although not shown in FIGS. 4A-4C, the opposite side of the core 414 may also include an RDL layer. The core 414 may be formed from one or more layers of silicon, glass, or organic material. In some examples, the core 414 may include layers of resin impregnated materials or other materials suitable for use in PCBs. The loop-back fan-out backside RDL 424 of the IC substrate 400 construction allows aligning a solder bump 402 formed on top of the IC substrate 400 to be substantially in line with a through via (TSV) 416 formed through the core 414. Thus, providing substantially the same high density solder bump layout efficiencies as the stacked backside RDL 120 construction (FIG. 1A).

Loop-back layouts of the RDL 424 include a trace 406 connected by a via 408 to a trace 408. The trace 406 is connected by a via 404. The solder bump 402 is formed on the via 404. The trace 410 is connected by a via 412 to the TSV 416 formed through the core 414. The traces may be, for example but are not limited to, looping (i.e., non-linear traces 406a, 410a as shown in FIG. 4A, or straight traces 406b, 410b as shown in FIG. 4A. The traces may include tear-drop shaped traces 406b, 410b. The center of the solder bump 402 may be aligned with the TSV 416 or within one-half of the solder bump pitch from the TSV 416 center. This design provides for lower stress and better reliability compared to the stacked backside RDL 120, while having substantially the same solder bump 402 density as provide by stacked backside RDL 120 construction, such that this layout configuration may be used for input-output and gigabit transfer circuits that require tight solder bump pitch (high density). The solder bumps 402 or solder balls may be, for example but are not limited to, controlled collapse chip connection (C4) solder bumps (or solder balls), copper filler plus solder cap (C2) solder bumps, microbumps (μbumps, ubumps), coined solder balls. The C4 solder bumps are solder bumps used to connect a chip (IC die) to external circuitry or other IC die(s) or interposers. C4 stands for controlled collapse chip connection when heated. C2 solder bumps are hard bumps that do not collapse and are smaller in diameter than C4 bumps. Therefore, allowing tighter bump pitches for very high density connections of an IC die. Microbumps are small, raised metal bumps or spheres that connect an IC die to a substrate such as an interposer or printed circuit board. The microbumps may also connect different chip layers and RDL layers in a stacked IC configuration. Coined solder balls are flattened into the shape of a coin.

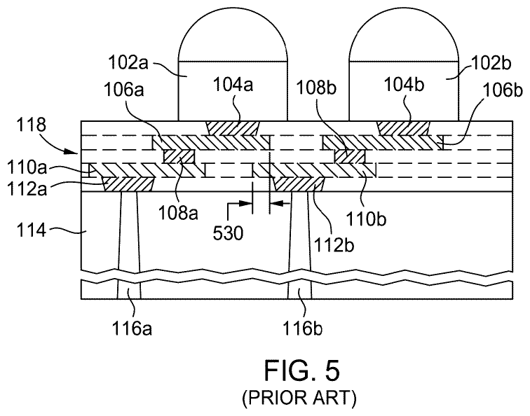

Referring to FIG. 5, depicted is a prior art schematic plan diagram of full fan-out backside RDL construction having an undesirable overlap of traces. Using full fan-out backside RDL 124 with straight traces in a dense solder bump 102 array can easily have significant trace overlap, as shown in FIG. 5, of a backside first metal layer 110 with an adjacent backside second metal layer 106 traces due to design rule constraints, thereby causing undesirable parasitic capacitance for high-speed gigabit transfer and/or input-output circuits.

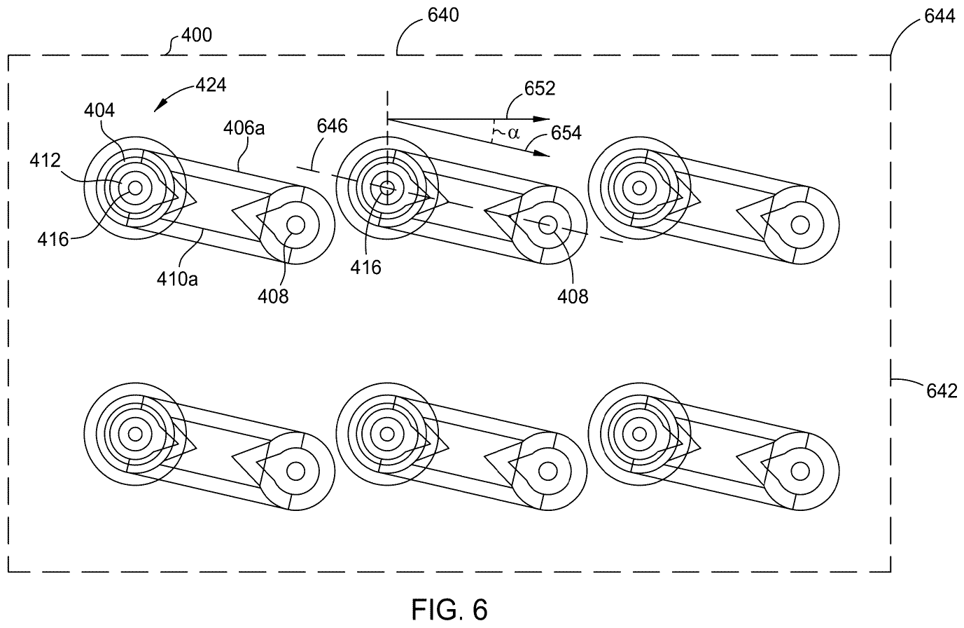

Referring to FIG. 6, depicted is a representative schematic plan diagram of RDL Line construction having traces 424rotated by an acute angle α on an interposer substrate 400. The interposer substrate 400 is generally rectangular. Two adjacent edges 640, 642 of the interposer substrate 400 are labeled in FIG. 6, and meet at a 90 degree corner 644. The acute angle α is defined between to rays 652, 654. In one example, the acute angle α is between about 25 to about 50 degrees. The ray 652 is parallel to one of the edges 640, 642 of the interposer substrate 400. In FIG. 6, the ray 652 is parallel to the edge 640. The ray 654 is parallel to an imaginary line 646 defined between the vias 408, 416. The trace overlap and parasitic capacitance therebetween may be substantially reduced in full fan-out backside RDL 424 or partial fan-out backside RDL 424 construction by the straight traces having an acute angle α to minimize the overlap or increase the distance there between traces on different RDL levels, thereby reducing parasitic capacitance. This design may also be used to connect high density TSVs 416 to high density solder bumps 402, replacing stacked backside RDL 120 construction.

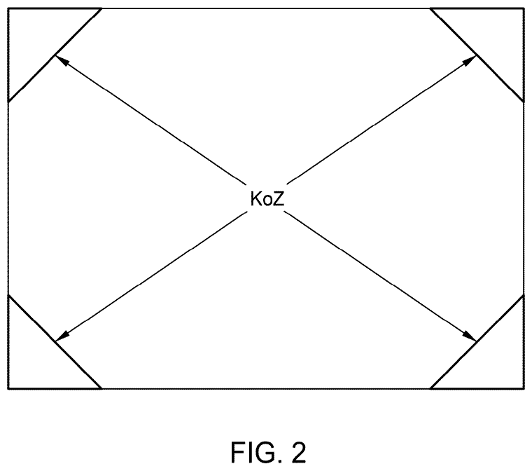

According to the teachings of this disclosure, the loop-back fan-out backside RDL 424 and “rotation” designs (e.g., designs having an acute angle α) have better reliability than stacked backside RDL 120, while maintaining tight solder bump pitch and/or high solder bump density that's needed for input-output and gigabit transfer circuits. With these new designs, the die corner Keep-Out-Zone (FIG. 2) for signal solder bumps 102 that may be required to mitigate the reliability risk of using stacked backside RDL 120 may be reduced or even eliminated, thereby reducing die size. According to the teachings of this disclosure, the layouts for the new RDL designs may be optimized to reduce parasitic RC (capacitances). One having ordinary skill in the art of integrated circuit layout design and the teachings of this disclosure can select which of these new RDL-LINE designs may best be used, depending on specific product requirements and in consideration of stress/reliability and parasitic RC tolerance.

The loop-back fan-out backside RDL 424 design has a distinctive “Loop-back” layout signature for a high density solder bump array, with the center of a solder bump within about half solder bump diameter pitch away from the center of the TSV or the via connected through an RDL to the rest of the interposer substrate 400. The “Rotated” full fan-out backside RDL or partial fan-out backside RDL designs also have distinctive layout signatures for a high density solder bump array, with the straight RDL trace rotated by an acute angle (for example, between about 25 and 50 degrees) to reduce parasitic capacitance between traces.

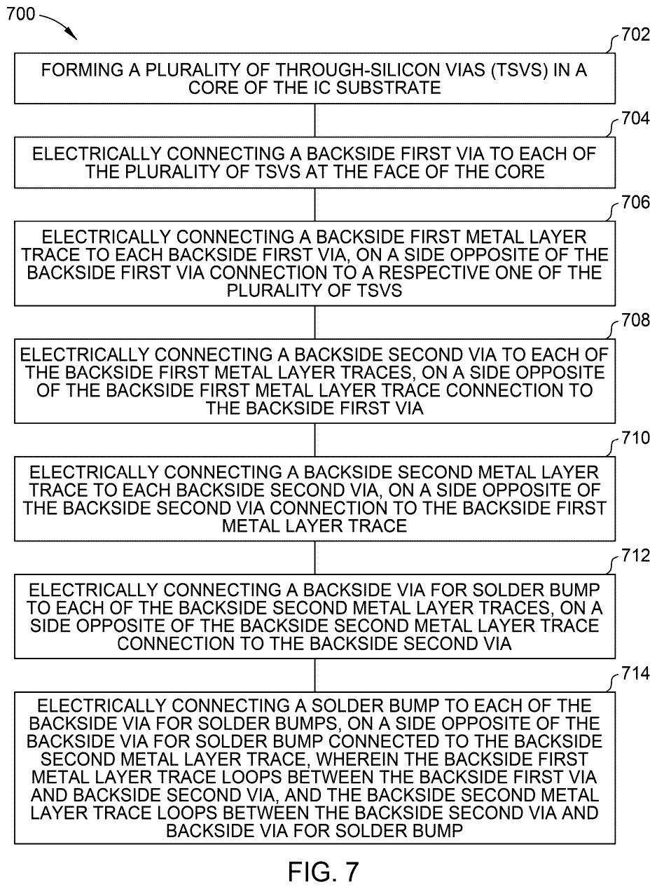

FIG. 7 is a flow diagram of one example of a method 700 for forming high density connections in a multi-level redistribution layer (RDL) attached to a core of an integrated circuit (IC) substrate. The method 700 beings at operation 702 by forming a plurality of through-silicon vias (TSVs) in the core of the IC substrate.

At operation 704, a backside first via is electrically connected to each of the plurality of TSVs at the face of the core.

At operation 706, a backside first metal layer trace is electrically connected to each backside first via, on a side opposite of the backside first via connection to a respective one of the plurality of TSVs.

At operation 708, a backside second via is electrically connected to each of the backside first metal layer traces, on a side opposite of the backside first metal layer trace connection to the backside first via;

At operation 710, a backside second metal layer trace is electrically connected to each backside second via, on a side opposite of the backside second via connection to the backside first metal layer trace.

At operation 712, a backside via for solder bump is electrically connected to each of the backside second metal layer traces, on a side opposite of the backside second metal layer trace connection to the backside second via.

At operation 714, a solder bump is electrically connected to each of the backside via for solder bumps, on a side opposite of the backside via for solder bump connected to the backside second metal layer trace. The backside first metal layer trace loops between the backside first via and backside second via. The backside second metal layer trace loops between the backside second via and backside via for solder bump.

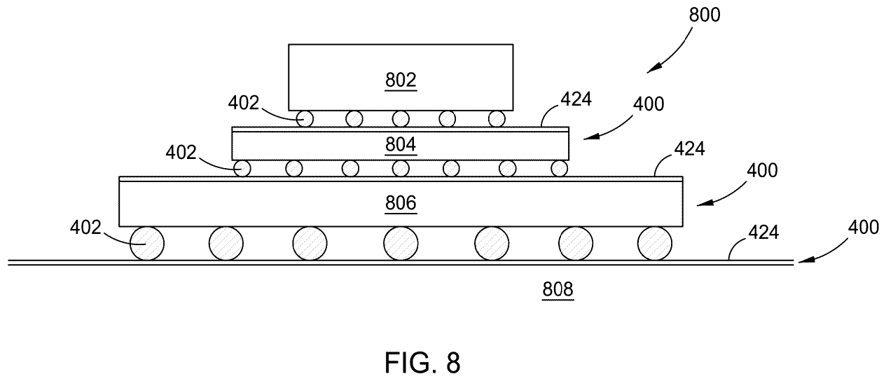

FIG. 8 depicts a schematic side view of a chip package 800 having a loop-back fan-out backside RDL 424. The chip package 800 includes one or more IC dies 802. When two or more IC dies 802 are present, the IC dies 802 may be vertically stacked and/or laterally spaced on the IC substrate 400. The IC substrate 400 may include an interposer stacked with a package substrate, package substrate, and/or a printed circuity board. In the example depicted in FIG. 8, the chip package 800 includes the IC substrate 400 in a form of an interposer 804 that is stacked on a package substrate 806. The package substrate 806 of the chip package 800 is connected to the printed circuit board 808. Optionally, any one or more of the interposer 804, the package substrate 806, the printed circuit board 808 may optionally include loop-back fan-out backside RDL 424, as illustrated in FIG. 8.

As will be appreciated by one skilled in the art and having the benefit of this disclosure, the embodiments disclosed herein may be embodied as a system, method, apparatus, or computer programmed product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

While the foregoing is directed to embodiments of the present invention, other and further embodiments of the invention may be devised without departing from the basic scope thereof, and the scope thereof is determined by the claims that follow.

What is claimed:

1. A method for forming high density connections in a multi-level redistribution layer (RDL) attached to a core of an integrated circuit (IC) substrate, comprising:
forming a plurality of through-silicon vias (TSVs) in the core of the IC substrate;
electrically connecting a backside first via to each of the plurality of TSVs at the face of the core;
electrically connecting a backside first metal layer trace to each backside first via, on a side opposite of the backside first via connection to a respective one of the plurality of TSVs;
electrically connecting a backside second via to each of the backside first metal layer traces, on a side opposite of the backside first metal layer trace connection to the backside first via;
electrically connecting a backside second metal layer trace to each backside second via, on a side opposite of the backside second via connection to the backside first metal layer trace;
electrically connecting a backside via for solder bump to each of the backside second metal layer traces, on a side opposite of the backside second metal layer trace connection to the backside second via; and
electrically connecting a solder bump to each of the backside via for solder bumps, on a side opposite of the backside via for solder bump connected to the backside second metal layer trace, wherein
the backside first metal layer trace loops between the backside first via and backside second via, and
the backside second metal layer trace loops between the backside second via and backside via for solder bump.

2. The method according to claim 1, wherein the backside first via, backside first metal layer trace, backside second via, backside second metal layer trace, and backside via for solder bump are supported and electrically insulated in non-conductive layers in a multi-level RDL.

3. The method according to claim 2, wherein the TSVs couple power, ground and circuit nodes through the IC substrate to the solder bumps through the multi-level RDL.

4. The method according to claim 1, wherein the backside first metal layer and backside second metal layer traces are tear dropped shaped traces.

5. The method according to claim 1, wherein the backside first metal layer and backside second metal layer traces are straight traces.

6. The method according to claim 1, wherein a center of a solder bump is substantially aligned to a TSV or within a half-solder bump pitch from a center of the TSV.

7. The method according to claim 1, further comprising rotating the backside first metal layer and backside second metal layer traces associated with adjacent TSVs so that they do not overlap.

8. The method according to claim 7, wherein the backside first metal layer and backside second metal layer traces associated with adjacent TSVs are rotated by an acute.

9. The method according to claim 8, wherein the acute angle is from about 25 to about 50 degrees.

10. The method according to claim 1, wherein the solder bumps are selected from a group consisting of C4 solder bumps, C2 solder bumps, microbumps, and coined solder balls.

11. An integrated circuit, comprising:
an integrated circuit (IC) substrate;
a plurality of through-silicon vias (TSVs) in a core of the IC substrate;
a multi-level redistribution layer (RDL) attached to a face of the core;
a plurality of backside first vias in the multi-level RDL, each backside first via electrically connected at the face of the IC die to a respective one of the plurality of TSVs;
a plurality of backside first metal layer traces in the multi-level RDL, each backside first metal layer trace electrically connected to a respective one of the plurality of backside first vias;
a plurality of backside second vias in the multi-level RDL, each backside second via electrically connected to a respective one of the plurality of backside first metal layer traces;
a plurality of backside second metal layer traces in the multi-level RDL, each backside second metal layer trace electrically connected to a respective one of the plurality of backside second vias;
a plurality of backside via for solder bumps in the multi-level RDL, each backside via for solder bump electrically connected to a respective one of the plurality of backside second metal layer traces; and
a plurality of solder bumps on the multi-level RDL, each solder bump electrically connected to a respective one of the plurality of backside via for solder bumps, wherein
the backside first metal layer traces loop between respective ones of the backside first vias and backside second vias, and
the backside second metal layer traces loop between respective ones of the backside second vias and backside via for solder bumps.

12. The integrated circuit according to claim 11, wherein the backside first via, backside first metal layer trace, backside second via, backside second metal layer trace, and backside via for solder bump are supported and electrically insulated in non-conductive layers in the multi-level RDL.

13. The integrated circuit according to claim 11, wherein the backside first metal layer and backside second metal layer traces are tear dropped shaped traces.

14. The integrated circuit according to claim 11, wherein the backside first metal layer and backside second metal layer traces are straight traces.

15. The integrated circuit according to claim 11, wherein the solder bumps are selected from a group consisting of C4 solder bumps, C2 solder bumps, microbumps, and coined solder balls.

16. An integrated circuit, comprising:
an integrated circuit (IC) substrate;
a plurality of through-silicon vias (TSVs) in a core of the IC substrate;
a multi-level redistribution layer (RDL) attached to a face of the core;
a plurality of backside first vias in the multi-level RDL, each backside first via electrically connected at the face of the core to a respective one of the plurality of TSVs;
a plurality of backside first metal layer traces in the multi-level RDL, each backside first metal layer trace electrically connected to a respective one of the plurality of backside first vias;
a plurality of backside second vias in the multi-level RDL, each backside second via electrically connected to a respective one of the plurality of backside first metal layer traces;
a plurality of backside second metal layer traces in the multi-level RDL, each backside second metal layer trace electrically connected to a respective one of the plurality of backside second vias;
a plurality of backside via for solder bumps in the multi-level RDL, each backside via for solder bump electrically connected to a respective one of the plurality of backside second metal layer traces; and
a plurality of solder bumps on the multi-level RDL, each solder bump electrically connected to a respective one of the plurality of backside via for solder bumps, wherein the backside first metal layer and backside second metal layer traces associated with adjacent TSVs are rotated so that they do not overlap.

17. The integrated circuit according to claim 16, wherein the backside first metal layer and backside second metal layer traces associated with adjacent TSVs are rotated by an acute angle relative to an edge of the IC substrate.

18. The integrated circuit according to claim 17, wherein the acute angle is from about 25 to about 50 degrees.

19. The integrated circuit according to claim 16, wherein the solder bumps are selected from a group consisting of C4 solder bumps, C2 solder bumps, microbumps, and coined solder balls.

20. The integrated circuit according to claim 16, wherein a first backside first metal layer trace of the plurality of backside first metal layer traces forms a non-linear path between the backside first and second vias that the first backside first metal layer trace is connected thereto.
